(19) United States
(12) Patent Application Publication
(10) Pub. No.: US 2011/0138615 A1
(43) Pub. Date: Jun. 16, 2011

(54) CARRIER FOR MANUFACTURING PRINTED CIRCUIT BOARD AND METHOD OF MANUFACTURING THE SAME AND METHOD OF MANUFACTURING PRINTED CIRCUIT BOARD USING THE SAME

(76) Inventors: Keung Jin Sohn, Gyunggi-do (KR); Chang Gun Oh, Gyunggi-do (KR); Tae Eun Chang, Gyunggi-do (KR)

(21) Appl. No.: 12/753,697

(22) Filed: Apr. 2, 2010

(30) Foreign Application Priority Data
Dec. 16, 2009 (KR) 10-2009-0125592

(51) Int. Cl. H05K 3/00; B23P 17/04; B23P 19/00

(52) U.S. Cl. 29/829; 29/428; 29/760

(57) ABSTRACT

Disclosed herein is a carrier for manufacturing a printed circuit board, including: a magnetic sheet; and a metal layer attached to at least one side of the magnetic sheet by magnetic properties of the magnetic sheet. The carrier is advantageous in that its structure can be simplified without performing a vacuum or releasing process at the time of the attachment and separation of the carrier, thus reducing process cost and process time and maintaining the size of a printed circuit board.

### CROSS REFERENCE TO RELATED APPLICATION

This application claims the benefit of Korean Patent Application No. 10-2009-0125592, filed Dec. 16, 2009, entitled “A carrier for manufacturing a printed circuit board and a method of manufacturing the same and a method of manufacturing a printed circuit board using the same”, which is hereby incorporated by reference in its entirety into this application.

### BACKGROUND OF THE INVENTION

1. Technical Field

The present invention relates to a carrier for manufacturing a printed circuit board, a method of manufacturing the same and a method of manufacturing a printed circuit board using the same.

2. Description of the Related Art

Generally, printed circuit boards (PCBs) are manufactured by patterning one or both sides of a substrate, composed of various thermosetting resins, using copper foil, and disposing and fixing ICs or electronic parts on the substrate to form an electric circuit and then coating the substrate with an insulator.

Recently, with the advancement of the electronics industry, electronic parts are increasingly required to be highly functionalized, light, thin, short and small. Thus, printed circuit boards loaded with such electronic parts are also required to be highly densified and thin.

In particular, in order to keep up with the thinning of printed circuit boards, a coreless substrate which can decrease thickness by removing a core and can shorten a signal processing time is attracting considerable attention. However, a coreless substrate needs a carrier serving as a support during a process because it does not have a core.

FIGS. 1 to 5 show a conventional method of manufacturing a printed circuit board using a carrier. Hereinafter, the conventional method of manufacturing a printed circuit board using a carrier will be described with reference to FIGS. 1 to 5.

First, as shown in FIG. 1, a carrier 10 is provided. Specifically, the carrier 10 is fabricated by sequentially forming adhesive layers 12, first metal layers 13 and second metal layers 14 on both sides of a copper clad laminate (CCL) 11 including an insulation layer and copper foil layers formed on both sides of the insulation layer. In this case, the carrier 10 is heated and pressed by a high-temperature and high-pressure press, and thus both ends of the adhesive layers 12 are attached to the copper clad laminate 11 and the second metal layer 14. Meanwhile, the first metal layer 13 is not attached to the second metal layer 14, but is only brought into contact with the second metal layer 14.

Subsequently, as shown in FIG. 2, build up layers 15 are formed on both sides of the carrier 10, and third metal layers 16 are formed on the outermost insulation layers of the build up layers 15. Here, the build up layers 15 are formed in a general manner, and may be additionally provided with vias for connecting build up circuit layers. Further, the third metal layers 16 are formed in order to prevent the warpage of the build up layers 15.

Subsequently, as shown in FIG. 3, the build up layers 15 are separated from the carrier 10. In this case, the build up layers 15 are separated from the carrier 10 by removing both ends of the adhesive layer 12, through which the copper clad laminate 11 and the second metal layer 14 are attached to each other, by a routing process. The first metal layer 13, which serves as a release layer, is easily separated from the second metal layer 14 when the adhesive layer 12 is removed, because the first metal layer 13 is not attached to the second metal layer 14.

Subsequently, as shown in FIG. 4, the second metal layer 14 and third metal layer 16 formed on the build up layer 15 are remove by etching.

Subsequently, as shown in FIG. 5, openings 17 for exposing pads 19 are formed in the outermost insulation layers of the build up layer 15, and then solder balls 18 are formed on the pads 19.

However, the conventional method of manufacturing a printed circuit board using a carrier is problematic in that both ends of a printed circuit board are removed by a to routing process, thus decreasing the size of a printed circuit board.

Further, the conventional method of manufacturing a printed circuit board using a carrier is problematic in that process cost and process time are increased because a vacuum method is used in order to strengthen the conjunction of the carrier 10 or a release layer is additionally formed in order to easily separate the build up layers 15 from the carrier 10.

### SUMMARY OF THE INVENTION

Accordingly, the present invention has been made to solve the above-mentioned problems, and the present invention provides a carrier for manufacturing a printed circuit board, by which the size of a printed circuit board is maintained even when the carrier is separated from the printed circuit board, a method of manufacturing the carrier, and a method of manufacturing a printed circuit board using the carrier.

Further, the present invention provides a carrier for manufacturing a printed circuit board, by which process cost and process time can be decreased by simplifying the structure of the carrier without using a vacuum method or inserting a release layer, a method of manufacturing the carrier, and a method of manufacturing a printed circuit board using the carrier.

An aspect of the present invention is to provide a carrier for manufacturing a printed circuit board, including: a magnetic sheet; and a metal layer attached to at least one side of the magnetic sheet by magnetic properties of the magnetic sheet.

Here, the magnetic sheet may contain glass fiber.

Further, the magnetic sheet may contain magnetic fillers having magnetic properties.

Further, the metal layer may be made of nickel (Ni), cobalt (Co), chromium (Cr), iron (Fe), or manganese (Mn).

Further, the magnetic sheet may include a sheet, and a magnetic metal layer formed on at least one side of the sheet.

Another aspect of the present invention provides a method of manufacturing a carrier for manufacturing a printed circuit board, including: providing a magnetic sheet; and attaching a metal layer to at least one side of the magnetic sheet by magnetic properties of the magnetic sheet.

Here, in the providing of the magnetic sheet, the magnetic sheet may contain glass fiber.

Further, in the providing of the magnetic sheet, the magnetic sheet may contain magnetic fillers having magnetic properties.

Further, in the attaching of the metal layer, the metal layer may be made of nickel (Ni), cobalt (Co), chromium (Cr), iron (Fe), or manganese (Mn).

Further, the providing of the magnetic sheet may include: providing a sheet; and forming a magnetic metal layer having magnetic properties on at least one side of the sheet.

Still another aspect of the present invention provides a method of manufacturing a printed circuit board using a carrier, including: attaching a metal layer to at least one side of a magnetic sheet by the magnetic properties of the magnetic sheet to provide a carrier; sequentially forming a first protective layer, a build up layer and a second protective layer on the metal layer; and separating the metal layer from the magnetic sheet and then removing the metal layer.

Here, in the providing of the carrier, the metal layer may be made of nickel (Ni), cobalt (Co), chromium (Cr), iron (Fe), or manganese (Mn).

Further, in the providing of the carrier, the magnetic sheet may contain glass fiber.

Further, in the providing of the carrier, the magnetic sheet may contain magnetic fillers having magnetic properties.

Further, the providing of the carrier may include: forming a magnetic metal layer having magnetic properties on at least one side of a sheet to provide a magnetic sheet; and attaching a metal layer to the magnetic metal layer by the magnetic properties of the magnetic metal layer.

Further, the separating the metal layer from the magnetic sheet may include: separating the metal layer from the magnetic sheet; removing the metal layer by etching; and forming openings for exposing pads of outermost circuit layers of the build up layer in the exposed first protective layer and second protective layer.

Still another aspect of the present invention provides a method of manufacturing a printed circuit board using a carrier, including: attaching a metal layer to at least one side of a magnetic sheet by the magnetic properties of the magnetic sheet to provide a carrier; sequentially forming a circuit layer and a build up layer on the metal layer; and separating the metal layer from the magnetic sheet and then removing the metal layer.

Here, the separating of the metal layer from the magnetic sheet may include: separating the metal layer from the magnetic sheet; removing the metal layer by etching; forming protective layers on both sides of the exposed build up layer; and forming openings for exposing pads of the circuit layer and outermost circuit layers of the build up layer in the protective layers.

Further, the circuit layer may be made of a metal different from the metal layer.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 5 are sectional views sequentially showing a conventional method of manufacturing a printed circuit board using a carrier;

FIG. 6 is a sectional view showing a carrier for manufacturing a printed circuit board according to a first embodiment of the present invention;

FIG. 7 is a sectional view showing a carrier for manufacturing a printed circuit board according to a second embodiment of the present invention;

FIGS. 8 and 9 are sectional views sequentially showing a method of manufacturing the carrier shown in FIG. 6;

FIGS. 10 to 12 are sectional views sequentially showing a method of manufacturing the carrier shown in FIG. 7;

FIGS. 13 to 17 are sectional views sequentially showing a method of manufacturing a printed circuit board using a carrier according to a first embodiment of the present invention; and

FIGS. 18 to 22 are sectional views sequentially showing a method of manufacturing a printed circuit board using a carrier according to a second embodiment of the present invention.

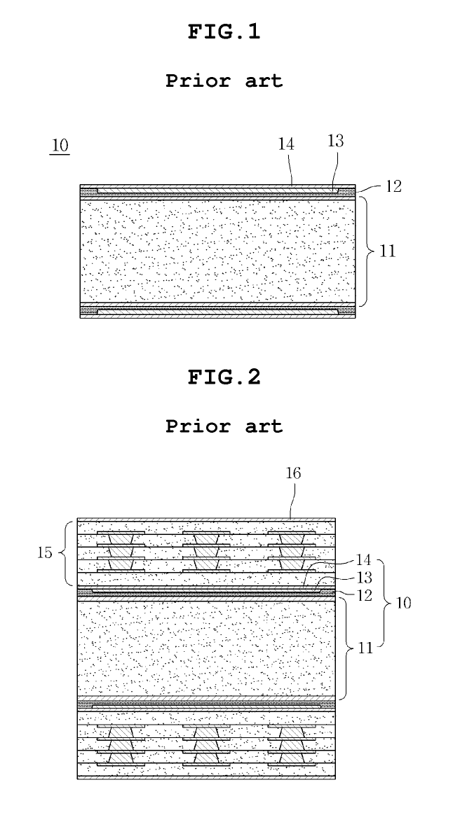

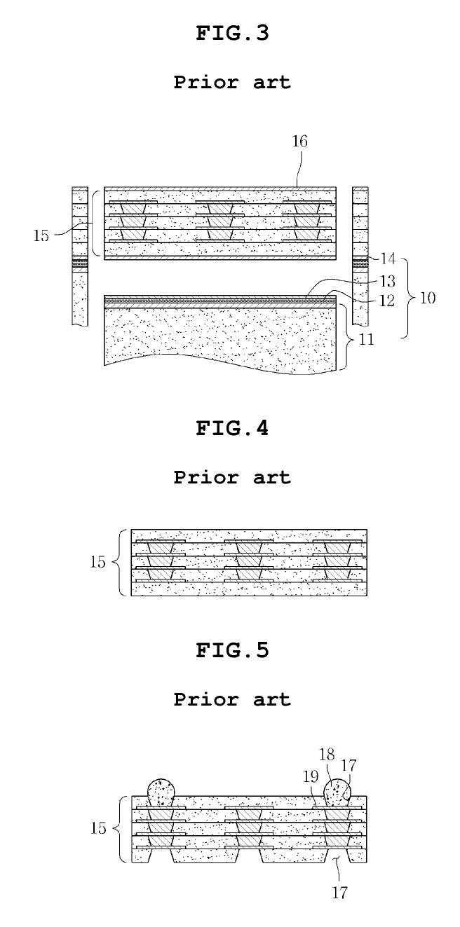

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. Further, in the following description, the terms “first”, “second” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

A Carrier for Manufacturing a Printed Circuit Board

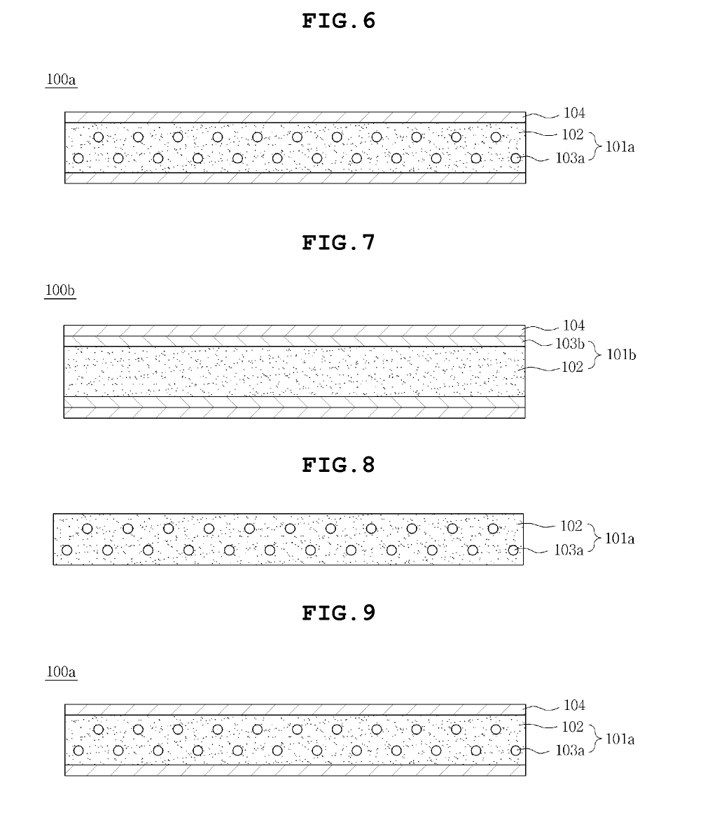

FIG. 6 is a sectional view showing a carrier for manufacturing a printed circuit board according to a first embodiment of the present invention. Hereinafter, the carrier 100a for manufacturing a printed circuit board according to a first embodiment of the present invention will be described with reference to FIG. 6.

As shown in FIG. 6, the carrier 100a for manufacturing a printed circuit board according to this embodiment includes a magnetic sheet 101a and a metal layer 104 formed on at least one side of the magnetic sheet 101a.

The magnetic sheet 101a, on one side or both sides of which the metal layers 104 are formed, includes a sheet 102 and magnetic fillers 103a.

Here, the sheet 102, which serves to support a printed circuit board at the time of manufacturing the printed circuit board, is required to have high strength. For example, the strength of the sheet 102 can be increased by the addition of glass fiber. Further, the sheet may be made of a non-insulating material, such as a metal, or an insulating material, such as an epoxy resin.

The magnetic fillers 103a are particles having magnetic properties, and the magnetic layers 104 are attached to the magnetic sheet 101a by the magnetic properties of the magnetic fillers 103a. The magnetic fillers 103 may be metal fillers such as nickel, iron or the like or may be ferrite fillers such as Ni—Cu—Zn ferrite, An—Zn ferrite or the like. Meanwhile, although it is shown in FIG. 6 that the magnetic fillers 103a are distributed in the sheet 102, the magnetic fillers 103a may be applied on the sheet 102.

The metal layers 104 are attached to one side or both sides of the magnetic sheet 101a.

Here, the metal layers 104 may be made of a material attaching to magnetic materials, such as nickel, cobalt, chromium, iron, manganese or the like. Meanwhile, the metal layers 104 may be made of a high-strength material because they constitute the carrier 100a together with the magnetic sheet 101a.

Further, although it is shown in FIG. 6 that the metal layers 104 are formed on both sides of the magnetic sheet 101a, the metal layer 104 may be formed on one side of the magnetic sheet 101a.

FIG. 7 is a sectional view showing a carrier for manufacturing a printed circuit board according to a second embodiment of the present invention. Hereinafter, the carrier 100b for manufacturing a printed circuit board according to a second embodiment of the present invention will be described with reference to FIG. 7. Here, the same reference numerals are used to designate the same or similar components, and redundant descriptions of this embodiment overlapping the first embodiment are omitted.

As shown in FIG. 7, the carrier 100b for manufacturing a printed circuit board according to this embodiment includes: a magnetic sheet 10 lb including a sheet 102 and magnetic metal layers 103b formed on both sides of the sheet 102; and metal layers 104 formed on both sides of the magnetic sheet 101b.

The magnetic metal layer 103b is formed on at least one side of the sheet 102, and is made of a magnetic material.

Here, the magnetic metal layer 103b may be made of a magnetic metal, such as nickel, cobalt, iron or an alloy thereof. Further, the magnetic metal layer 103b is not limited to metals, and may be a polymer magnet or an electromagnet.

Meanwhile, the metal layers 104 are attached to the magnetic metal layers 103b by the magnetic properties of the magnetic metal layers 103b.

A Method of Manufacturing a Carrier for Manufacturing a Printed Circuit Board

FIGS. 8 and 9 are sectional views sequentially showing a method of manufacturing a carrier for manufacturing a printed circuit board according to a first embodiment of the present invention. Hereinafter, the method of manufacturing a carrier 100a for manufacturing a printed circuit board according to a first embodiment of the present invention will be described with reference to FIGS. 8 and 9.

First, as shown in FIG. 8, a magnetic sheet 101a is provided.

In this case, the magnetic sheet 101a may include a sheet 102 containing a reinforcing material, such as glass fiber, and magnetic fillers 103a. For example, when the sheet 102 is made of an insulating material such as an epoxy resin, the sheet 102 can be formed into the magnetic sheet 101a having excellent magnetic properties and high strength by impregnating glass fiber and magnetic fillers 103 into the sheet 102 and then curing the insulating material. Further, the magnetic fillers 103a may also be applied on the sheet 102 by a spray method.

Subsequently, as shown in FIG. 9, metal layers 104 are formed on one or both sides of the magnetic sheet 101a.

In this case, the metal layers 104 can be attached to the magnetic sheet 101a by the magnetic properties of the magnetic sheet 101a. Meanwhile, the metal layers 104 and the magnetic sheet 101 a may be attached to each other to such a degree that foreign materials, such as an etchant and the like, do not infiltrate therebetween.

Through the above processes, the carrier 100a, shown in FIG. 9, according to the first embodiment of the present invention is manufactured.

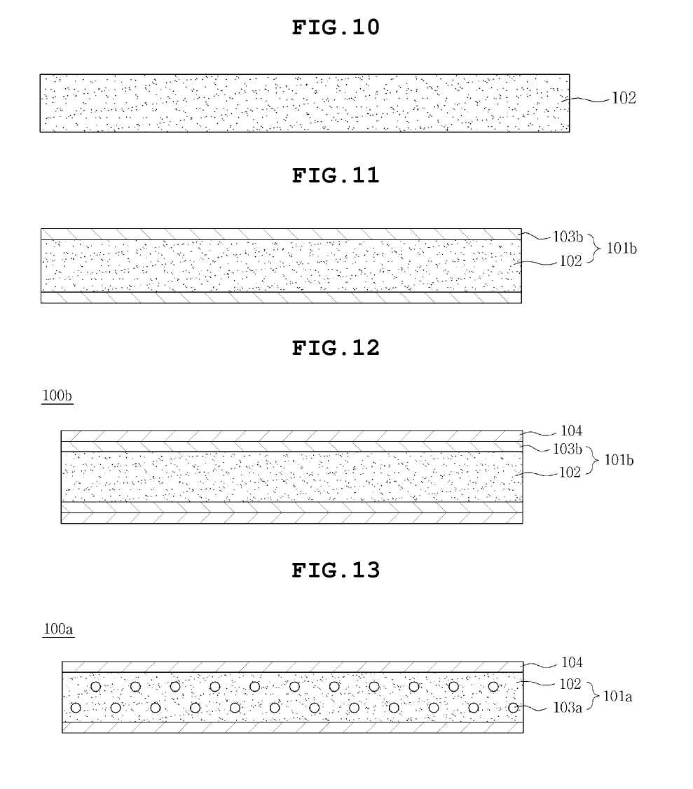

FIGS. 10 to 12 are sectional views sequentially showing a method of manufacturing the carrier for manufacturing a printed circuit board according to the second embodiment of the present invention. Hereinafter, the method of manufacturing the carrier 100b for manufacturing a printed circuit board according to the second embodiment of the present invention will be described with reference to FIGS. 10 to 12. Here, the same reference numerals are used to designate the same or similar components, and redundant descriptions of this embodiment overlapping the first embodiment are omitted.

First, as shown in FIGS. 10 and 11, a sheet 102 is provided, and then magnetic metal layers 103b are formed on one or both sides of the sheet 102 to form a magnetic sheet 101b.

In this case, the magnetic metal layers 103b may be formed on the sheet 102 by metal adhesion or sputtering.

Subsequently, as shown in FIG. 12, metal layers 104 are attached to the magnetic sheet 101b.

In this case, the metal layers 104 can be attached to the magnetic metal layers 103b by the magnetic properties of the magnetic metal layers 103b of the magnetic sheet 101b.

Through the above processes, the carrier 100b, shown in FIG. 12, according to the second embodiment of the present invention is manufactured.

A Method of Manufacturing a Printed Circuit Board Using a Carrier

FIGS. 13 to 17 are sectional views sequentially showing a method of manufacturing a printed circuit board 200a using a carrier according to a first embodiment of the present invention. Hereinafter, the method of manufacturing a printed circuit board 200a using a carrier according to a first embodiment of the present invention will be described with reference to FIGS. 13 to 17.

It is described in this embodiment that printed circuit boards 200a are formed on both sides of a carrier 100a, but, in the present invention, a printed circuit board 200a may be formed on one side of a carrier 100a. Further, it is described in this embodiment that the carrier 100a according to the first embodiment is used, but, in the present invention, the carrier 100b according to the second embodiment may be used.

First, as shown in FIG. 13, metal layers 104 are attached to a magnetic sheet 101a containing magnetic fillers 103a to provide a carrier 100a for manufacturing a printed circuit board.

In this case, when a printed circuit board 200a is formed on only one side of the carrier 100a, the metal layer 104 may be attached to only one side of the magnetic sheet 101a.

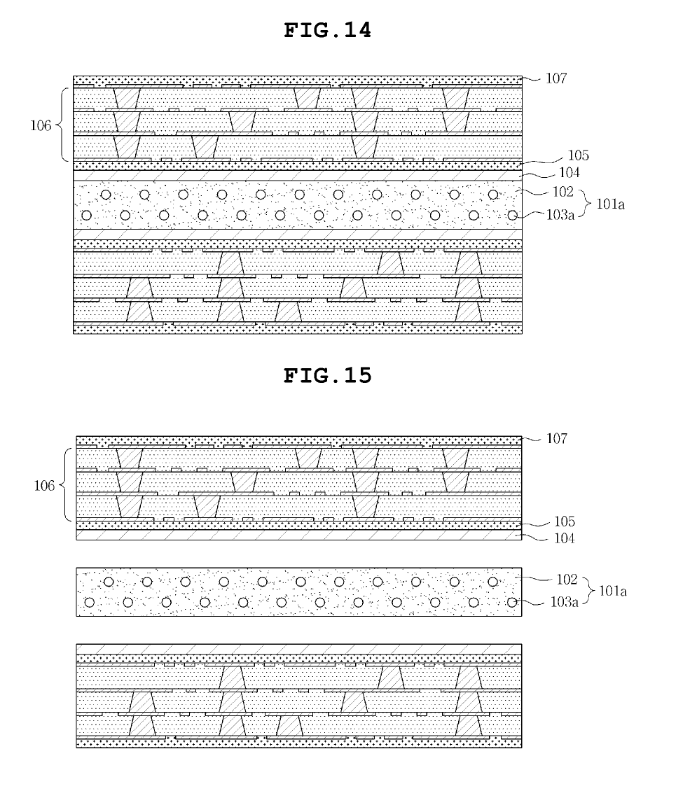

Subsequently, as shown in FIG. 14, a first protective layer 105, a build up layer 106 and a second protective layer 107 are sequentially formed on each of the metal layers 104.

Specifically, a first protective layer 105 is formed on each of the metal layers 104 of the carrier 100a. Here, the first protective layer 105, which serves to protect the outermost circuit layer of a build up layer 16, may be formed of dry film type solder resist or liquid solder resist.

Then, a build up layer 106 is formed on the first protective layer 105. In FIG. 15, a three-layered build up layer is shown, but a single-layered or multi-layered build up layer may be formed. Meanwhile, the build up layer 106 may include a build up insulation layer and a build up circuit layer, and may be formed using a general method. For example, the build up circuit layer may be formed by a semi-additive process (SAP).

Then, a second protective layer 107 may be formed on the build up layer 16. In this case, the second protective layer 107 may be made of the same material as the first protective layer 105.

Subsequently, as shown in FIG. 15, the metal layer 104 is separated from the magnetic sheet 101a.

In this case, since the metal layer 104 and the magnetic sheet 101a are attached to each other by their magnetic properties, they can be relatively easily separated from each other. Further, since an additional routing process is not required, the size of a printed circuit board can be maintained.

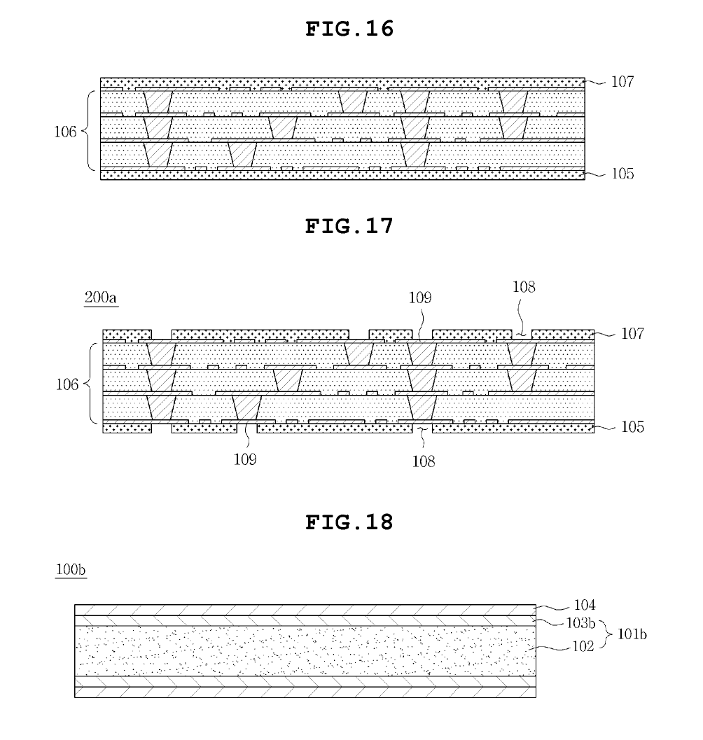

Subsequently, as shown in FIG. 16, the metal layer 104 attached to the first protective layer 105 is removed.

In this case, the metal layer 104 may be removed by an etching process. Further, it is preferable to prevent a build up circuit layer of the build up layer 16 from being unexpectedly etched by making the metal layer 140 using a metal different from the build up circuit layer.

Subsequently, as shown in FIG. 17, openings 108 are formed in the first protective layer 105 and the second protective layer 107.

In this case, pads 109 of the outermost circuit layer of the build up layer 106 can be exposed through the openings 18. Further, the openings may be formed by laser drilling or machine drilling

Through the above processes, the printed circuit board 200a, shown in FIG. 17, according to the first embodiment of the present invention is manufactured.

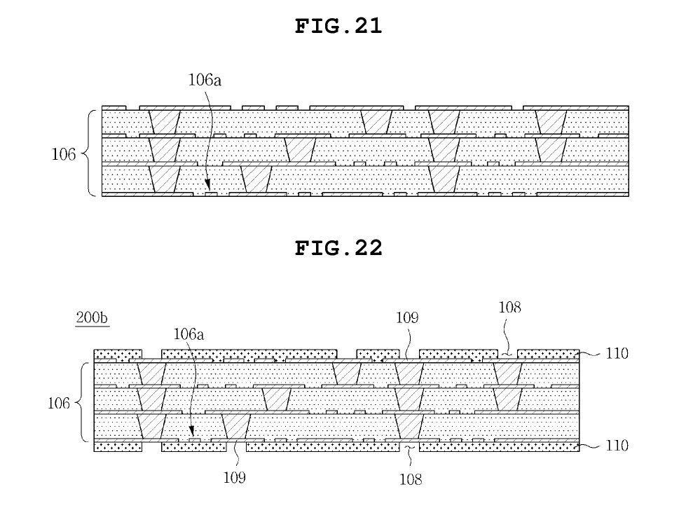

FIGS. 18 to 22 are sectional views sequentially showing a method of manufacturing a printed circuit board 200b using a carrier according to a second embodiment of the present invention. Hereinafter, the method of manufacturing a printed circuit board 200b using a carrier according to a second embodiment of the present invention will be described with reference to FIGS. 18 to 22. Here, the same reference numerals are used to designate the same or similar components, and redundant descriptions of this embodiment overlapping the first embodiment are omitted.

Meanwhile, it is described in this embodiment that the carrier 100b according to the second embodiment is used, but, in the present invention, the carrier 100a according to the first embodiment may be used.

First, as shown in FIG. 18, magnetic metal layers 103b are formed on both sides of a sheet 102 to form a magnetic sheet 101b, and then metal layers 104 are attached to the magnetic metal layers 103b to provide a carrier 100b for manufacturing a printed circuit board.

In this case, when a printed circuit board 200b is formed on only one side of the carrier 100b, the magnetic metal layer 103b and the metal layer 104 may be sequentially formed on only one side of the sheet 102.

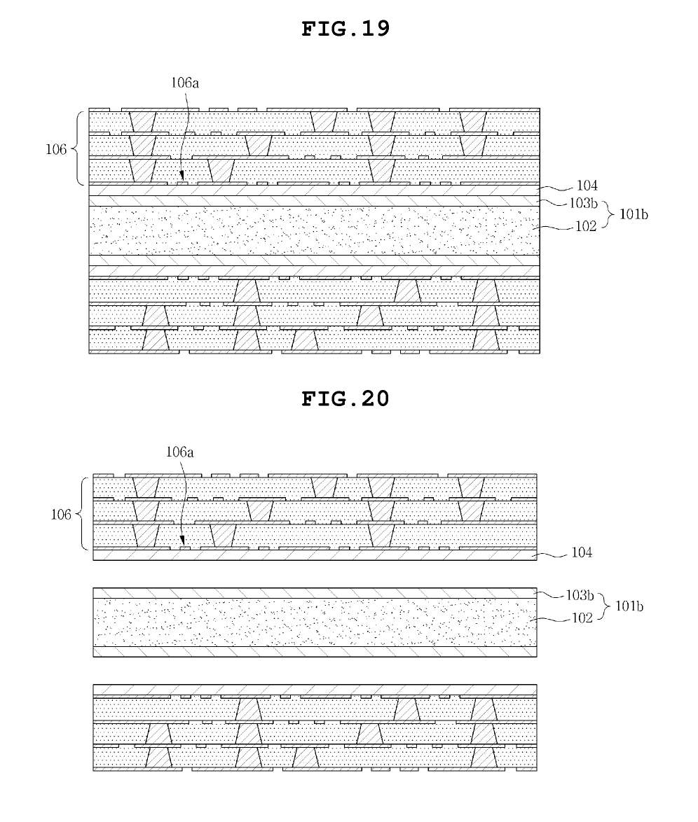

Subsequently, as shown in FIG. 19, a circuit layer 106a and a build up layer 106 are sequentially formed on each of the metal layers 104.

In this case, the circuit layer 106a, which becomes an outermost circuit layer of the build up layer 106 later, may be formed using a subtractive process, an additive process, a semi-additive process, a modified semi-additive process or the like. Further, the circuit layer 106a may be made of an electroconductive metal, such as gold, silver, copper, nickel or the like, and may be made of a metal different from the metal layer 104 which is to be removed later.

Subsequently, as shown in FIGS. 20 to 22, the metal layer 104 is separated from the magnetic metal layer 103b, and then the metal layer 104 is removed from the build up layer 106. Then, protective layers 110 are formed on the exposed outermost layers of the to build up layer 106, and then openings 108 for exposing pads 109 are formed in the protective layers 110.

In this case, when the magnetic metal layer 103b is formed of an electromagnet, the attractive force between the magnetic metal layer 103b and the metal layer 104 can be removed by blocking the electric current flowing through the electromagnet.

Through the above processes, the printed circuit board 200b, shown in FIG. 22, according to the second embodiment of the present invention is manufactured.

As described above, according to the present invention, a carrier includes a magnetic sheet and metal layers attached to the magnetic sheet by magnetic properties, so that an additional cutting process is not required when a printed circuit board is separated from the carrier, thereby maintaining the size of a printed circuit board.

Further, according to the present invention, the structure of a carrier can be simplified by using the magnetic properties of a magnetic sheet, thus reducing process cost and process time.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

What is claimed is:

1. A carrier for manufacturing a printed circuit board, comprising:
a magnetic sheet; and
a metal layer attached to at least one side of the magnetic sheet by magnetic properties of the magnetic sheet.

2. The carrier for manufacturing a printed circuit board according to claim 1, wherein the magnetic sheet contains glass fiber.

3. The carrier for manufacturing a printed circuit board according to claim 1, wherein the magnetic sheet contains magnetic fillers having magnetic properties.

4. The carrier for manufacturing a printed circuit board according to claim 1, wherein the magnetic sheet comprises:
a sheet; and
a magnetic metal layer formed on at least one side of the sheet.

5. The carrier for manufacturing a printed circuit board according to claim 1, wherein the metal layer is made of nickel (Ni), cobalt (Co), chromium (Cr), iron (Fe), or manganese (Mn).

6. A method of manufacturing a carrier for manufacturing a printed circuit board, comprising:
providing a magnetic sheet; and
attaching a metal layer to at least one side of the magnetic sheet by magnetic properties of the magnetic sheet.

7. The method of manufacturing a carrier for manufacturing a printed circuit board according to claim 6, wherein, in the providing of the magnetic sheet, the magnetic sheet contains glass fiber.

8. The method of manufacturing a carrier for manufacturing a printed circuit board according to claim 6, wherein, in the providing of the magnetic sheet, the magnetic sheet contains magnetic fillers having magnetic properties.

9. The method of manufacturing a carrier for manufacturing a printed circuit board according to claim 6, wherein the providing of the magnetic sheet comprises:
providing a sheet; and
forming a magnetic metal layer having magnetic properties on at least one side of the sheet.

10. The method of manufacturing a carrier for manufacturing a printed circuit board according to claim 6, wherein, in the attaching of the metal layer, the metal layer is made of nickel (Ni), cobalt (Co), chromium (Cr), iron (Fe), or manganese (Mn).

11. A method of manufacturing a printed circuit board using a carrier, comprising:
attaching a metal layer to at least one side of a magnetic sheet by magnetic properties of the magnetic sheet to provide a carrier;
sequentially forming a first protective layer, a build up layer and a second protective layer on the metal layer; and
separating the metal layer from the magnetic sheet and then removing the metal layer.

12. The method of manufacturing a printed circuit board using a carrier according to claim 11, wherein, in the providing of the carrier, the metal layer is made of nickel (Ni), cobalt (Co), chromium (Cr), iron (Fe), or manganese (Mn).

13. The method of manufacturing a printed circuit board using a carrier according to claim 11, wherein, in the providing of the carrier, the magnetic sheet contains glass fiber.

14. The method of manufacturing a printed circuit board using a carrier according to claim 11, wherein, in the providing of the carrier, the magnetic sheet contains magnetic fillers having magnetic properties.

15. The method of manufacturing a printed circuit board using a carrier according to claim 11, wherein the providing of the carrier comprises:
forming a magnetic metal layer having magnetic properties on at least one side of a sheet to provide a magnetic sheet; and
attaching a metal layer to the magnetic metal layer by magnetic properties of the magnetic metal layer.

16. The method of manufacturing a printed circuit board using a carrier according to claim 11, wherein the separating of the metal layer from the magnetic sheet comprises:
separating the metal layer from the magnetic sheet;
removing the metal layer by etching; and
forming openings for exposing pads of outermost circuit layers of the build up layer in the exposed first protective layer and second protective layer.

17. A method of manufacturing a printed circuit board using a carrier, comprising:
attaching a metal layer to at least one side of a magnetic sheet by magnetic properties of the magnetic sheet to provide a carrier;
sequentially forming a circuit layer and a build up layer on the metal layer; and
separating the metal layer from the magnetic sheet and then removing the metal layer.

18. The method of manufacturing a printed circuit board using a carrier according to claim 17, wherein the separating of the metal layer from the magnetic sheet comprises:
separating the metal layer from the magnetic sheet;
removing the metal layer by etching;
forming protective layers on both sides of the exposed build up layer; and
forming openings for exposing pads of the circuit layer and outermost circuit layers of the build up layer in the protective layers.

19. The method of manufacturing a printed circuit board using a carrier according to claim 17, wherein the circuit layer is made of a metal different from the metal layer.
